(19) United States
(12) Patent Application Publication
(10) Pub. No.: US 2026/0206408 A1
(43) Pub. Date: Jul. 16, 2026

(54) COMPOUND, LIGHT-EMITTING LAYER RAW MATERIAL, ORGANIC LIGHT-EMITTING DEVICE, ELECTRONIC DEVICE, AND PREPARATION METHOD

(71) Applicant: Huawei Technologies Co., Ltd., Shenzhen (CN)

(72) Inventors: Wei Li, Osaka (JP); Yasunori Kijima, Tokyo (JP)

(21) Appl. No.: 19/563,609

(22) Filed: Mar. 11, 2026

Related U.S. Application Data
(63) Continuation of application No. PCT/CN2024/117953, filed on Sep. 10, 2024.

(30) Foreign Application Priority Data
Sep. 12, 2023 (CN) 202311184342.9

(51) Int. Cl. H10K 50/12; C07F 7/08; H10K 85/30; H10K 85/40; H10K 85/60

(52) U.S. Cl. CPC H10K 50/121; C07F 7/0812; H10K 85/346; H10K 85/40; H10K 85/654; H10K 85/6572; H10K 85/6574

(57) ABSTRACT

An example compound includes a tetraphenyl silyl group having a plurality of benzene rings, a carbazole group connected to a first benzene ring of the tetraphenyl silyl group, and a triazine group connected to a second benzene ring of the tetraphenyl silyl group different from the first benzene ring. The triazine group includes a triazine ring, a first aryl substituent, and a second aryl substituent connected to the triazine ring. An example light-emitting layer raw material includes a guest material and a host material, the host material including the compound. An example organic light-emitting device includes a cathode, an anode, and a light-emitting layer located between the cathode and the anode, the light-emitting layer including the guest material and the host material.

### CROSS-REFERENCE TO RELATED APPLICATIONS

This application is a continuation of International Application No. PCT/CN2024/117953, filed on Sep. 10, 2024, which claims priority to Chinese Patent Application No. 202311184342.9, filed on Sep. 12, 2023. The disclosures of the aforementioned applications are hereby incorporated by reference in their entirety.

### TECHNICAL FIELD

This disclosure relates to the field of display technologies, and in particular, to a compound, a light-emitting layer raw material, an organic light-emitting device, an electronic device, and a preparation method.

### BACKGROUND

An organic light-emitting diode (OLED) includes a cathode, an organic functional layer, and an anode. The organic functional layer includes a light-emitting layer, and the light-emitting layer can emit red light, green light, and blue light. Raw materials for preparing the light-emitting layer usually include a host material and a guest material, to improve efficiency and a lifetime.

Because a blue light-emitting energy level is greater than 2.6 eV and close to bond energy of a molecule, it is critical to improve efficiency and a lifetime of a blue light-emitting layer. A blue light host material has a significant impact on the efficiency and the lifetime of the blue light-emitting layer. A common blue light host material in related technologies includes mCP, mCBP, oCBP, SiCzCz, mCBP-2CN, TSPO1, PPF, SiTrzCz2, and the like.

However, the blue light host material easily causes a combination zone of holes and electrons to offset to a hole transport side or an electron transport side, causing low light-emitting efficiency.

### SUMMARY

In view of this, this disclosure provides a compound, a light-emitting layer raw material, an organic light-emitting device, an electronic device, and a preparation method, to resolve some challenges existing in related technologies.

According to an aspect, a compound is provided. The compound includes a tetraphenyl silyl group, a carbazole group, and a triazine group, and the carbazole group and the triazine group are respectively connected to different benzene rings of the tetraphenyl silyl group.

The triazine group includes a triazine ring and a first aryl substituent and a second aryl substituent that are connected to the triazine ring.

The compound provided in this embodiment of this disclosure uses the tetraphenyl silyl group as a central group of the compound, silicon in the tetraphenyl silyl group is SP3 hybridized, and a spatial structure of the silicon is a regular tetrahedron structure. This can effectively interrupt conjugation in a molecule of the compound, and help the molecule of the compound maintain a wide bandgap. The compound is connected to the carbazole group and the triazine group on different benzene rings of the tetraphenyl silyl group, where the carbazole group is electron-rich, facilitating hole injection and transport, and is used as a hole transport group. The triazine group is electron-deficient, facilitating electron injection and transport. It can be learned that the compound has both a hole transport group and an electron transport group, and therefore has bipolarity. The bipolar compound can achieve a balance between hole transport and electron transport. When the bipolar compound is used as a host material of a light-emitting layer of an OLED, this not only facilitates an exciton recombination zone to be located at a center of the light-emitting layer, but also facilitates widening of the exciton recombination zone. In addition, the triazine group includes the triazine ring and the first aryl substituent and the second aryl substituent that are connected to the triazine ring. A structure of the triazine group has advantages of a high triplet energy level and stable electron injection energy. With the structural features of the compound, the compound has a high triplet energy level when used as the host material of the light-emitting layer. In this way, excitons can be effectively injected into a guest material and a sensitizer and energy transfer can be performed, thereby improving light-emitting efficiency. In addition, this helps reduce a difference between triplet and singlet energy levels, so that a triplet exciton can be converted into a singlet exciton through reverse intersystem crossing, to reduce triplet annihilation, thereby prolonging a lifetime.

In some possible implementations, the first aryl substituent and the second aryl substituent are independently selected from phenyl, dibenzofuranyl, naphthyl, anthryl, phenanthryl, fluorenyl, benzanthracenyl, benzophenanthrenyl, pyrenyl, or dibenzothiophenyl.

In some possible implementations, there are one or two carbazole groups; and/or there are one or two triazine groups.

In some possible implementations, the tetraphenyl silyl group, the carbazole group, the first aryl substituent, and the second aryl substituent are separately substituted or unsubstituted, and for those groups having substituted groups, the substituted groups are independently selected from alkyl, aryl, cyano, deuterium atom, or halogen atom.

In some possible implementations, a chemical structural formula of the compound is shown as follows:

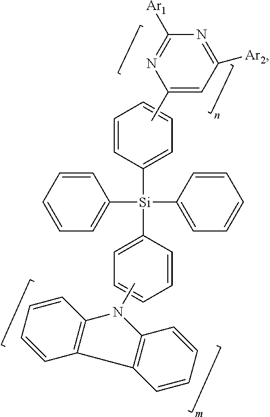

where
Ar₁ is the first aryl substituent, and Ar₂ is the second aryl substituent; and m and n are independently selected from integers from 1 to 5.

In some possible implementations, a chemical structural formula of the compound is shown as follows:

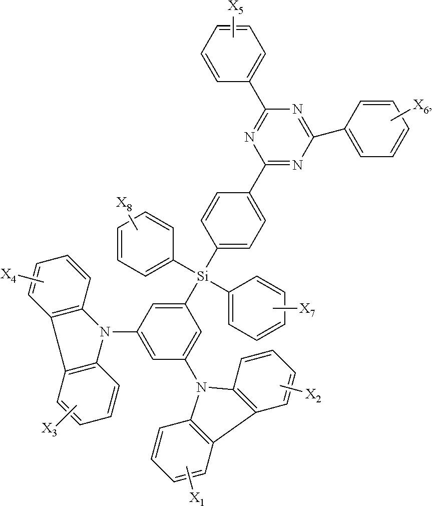

where
the tetraphenyl silyl group, the carbazole group, phenyl corresponding to the first aryl substituent, and phenyl corresponding to the second aryl substituent are separately substituted or unsubstituted; and
X₁ to X₈ are substituted groups, and the substituted groups are independently elected from alkyl, aryl, cyano, deuterium atom, or halogen atom.

In some possible implementations, a chemical structural formula of the compound is shown as follows:

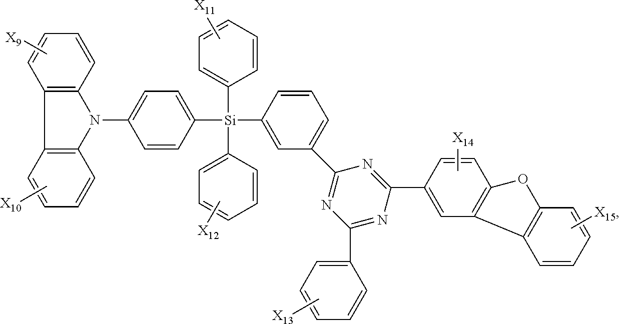

where
the tetraphenyl silyl group, the carbazole group, phenyl corresponding to the first aryl substituent, and dibenzofuranyl corresponding to the second aryl substituent are separately substituted or unsubstituted; and
X₉ to X₁₅ are substituted groups, and the substituted groups are independently selected from alkyl, aryl, cyano, deuterium atom, or halogen atom.

According to another aspect, an embodiment of this disclosure further provides a light-emitting layer raw material. The light-emitting layer raw material includes a host material and a guest material, and any one of the foregoing compounds is used as the host material.

The light-emitting layer raw material provided in this embodiment of this disclosure can be used in an OLED to form a light-emitting layer, and the foregoing compound can be used as a host material in the light-emitting layer. The light-emitting layer raw material provided in this embodiment of this disclosure has all the advantages of the bipolar compound.

In some possible implementations, the host material is a blue light host material. The compound may be used alone as the blue light host material, or may be used with another host material to form the blue light host material.

In some possible implementations, a mass percentage of the host material in the light-emitting layer material is 70% to 99%.

In some possible implementations, the light-emitting layer raw material further includes a sensitizer, and a mass percentage of the sensitizer in the light-emitting layer material is 5% to 30%.

The light-emitting layer raw material provided in this embodiment of this disclosure may be used as a blue light-emitting layer raw material. The guest material that is collaborative with the host material based on the compound may be a fluorescent material, a phosphorescent material, or a thermally activated delayed fluorescence (TADF) material. The sensitizer that is collaborative with the host material based on the compound may be a phosphorescent material or a TADF material.

In another aspect, an embodiment of this disclosure further provides an organic light-emitting device. The organic light-emitting device includes a cathode, an anode, and an organic functional layer, and the organic functional layer includes a light-emitting layer and is located between the cathode and the anode. The light-emitting layer is prepared by using any one of the foregoing light-emitting layer raw materials.

The organic light-emitting device provided in this embodiment of this disclosure is an organic electroluminescent device (OLED), and has all the advantages of the foregoing light-emitting layer raw material, so that the organic light-emitting device has high efficiency and a longer lifetime.

In some examples, the organic functional layer includes the light-emitting layer (EML) and a hole transport zone and an electron transport zone that are located on two sides of the light-emitting layer, where the anode, the hole transport zone, the light-emitting layer, the electron transport zone, and the cathode are sequentially stacked.

The hole transport zone includes at least one of a hole transport layer (HTL), a hole injection layer (HIL), and an electron blocking layer (EBL). The electron transport zone includes at least one of an electron transport layer (ETL), an electron injection layer (EIL), and a hole blocking layer (HBL).

According to still another aspect, an embodiment of this disclosure further provides an electronic device. The electronic device includes the foregoing organic light-emitting device.

According to yet another aspect, an embodiment of this disclosure further provides a preparation method of a compound, where the compound is as described in any one of the foregoing.

The preparation method of the compound includes: determining, based on a chemical structure of the compound, an organoboron monomer and a halide monomer that are used to synthesize the compound; and performing a coupling reaction on the organoboron monomer and the halide monomer, to prepare the compound.

In some possible implementations, the compound is directly synthesized by performing the coupling reaction on the organoboron monomer and the halide monomer.

The organoboron monomer contains a carbazole group and a tetraphenyl silyl group, and the halide monomer contains a triazine group.

The organoboron monomer is prepared by using the following method: providing tetraphenyl silane having a carbazole group and a halogen group; and performing a borylation reaction on the tetraphenyl silane having the carbazole group and the halogen group and bis(pinacolato)diboron, to obtain the organoboron monomer.

In some possible implementations, a precursor of the compound is synthesized by performing the coupling reaction on the organoboron monomer and the halide monomer; and the compound is prepared by grafting an aryl substituent onto the precursor of the compound.

The organoboron monomer contains a carbazole group and a tetraphenyl silyl group, and the halide monomer contains a triazine group.

The organoboron monomer is prepared by using the following method: providing tetraphenyl silane having a carbazole group and a halogen group; and performing a borylation reaction on the tetraphenyl silane having the carbazole group and the halogen group and bis(pinacolato)diboron, to obtain the organoboron monomer.

### BRIEF DESCRIPTION OF THE DRAWINGS

FIG. 1 is a diagram of a structure of an example organic light-emitting device according to an embodiment of this disclosure; and

FIG. 2 is a diagram of a structure of another example organic light-emitting device according to an embodiment of this disclosure.

Reference numerals: 100: substrate, 200: anode, 300: hole injection layer, 400: hole transport layer, 500: light-emitting layer, 600: electron transport layer, 700: electron injection layer, 800: cathode, 901: electron blocking layer, and 902: hole blocking layer.

### DETAILED DESCRIPTION OF ILLUSTRATIVE EMBODIMENTS

The following clearly and completely describes the technical solutions in embodiments of this disclosure with reference to accompanying drawings in embodiments of this disclosure. It is clear that the described embodiments are a part but not all of embodiments of this disclosure. All other embodiments obtained by a person of ordinary skill in the art based on embodiments of this disclosure without creative efforts shall fall within the protection scope of this disclosure.

Example embodiments are described in detail herein, and examples of the example embodiments are presented in the accompanying drawings. When the following description relates to the accompanying drawings, unless specified otherwise, same numbers in different accompanying drawings represent a same or similar element. Implementations described in the following example embodiments do not represent all implementations consistent with this disclosure. On the contrary, they are only examples of apparatuses and methods that are described in the appended claims in detail and that are consistent with some aspects of this disclosure.

A light-emitting layer has a significant impact on light-emitting performance of an OLED. The light-emitting layer includes a red light-emitting layer that emits red light, a green light-emitting layer that emits green light, and a blue light-emitting layer that emits blue light, to display primary colors: red, green, and blue. Because a blue light-emitting energy level is greater than 2.6 eV and close to bond energy of a molecule, it is critical to improve efficiency and a lifetime of the blue light-emitting layer.

The preparation raw material of the blue light-emitting layer includes at least a blue light host material and a blue light guest material, and may further include a sensitizer. The blue light host material has a higher content, and plays an important role in charge transport, exciton generation, and exciton transport. Therefore, the blue light host material has a significant impact on improving the efficiency and the lifetime of the blue light-emitting layer.

A common blue light host material in related technologies includes mCP, mCBP, oCBP, SiCzCz, mCBP-2CN, TSPO1, PPF, SiTrzCz2, and the like. mCP, mCBP, oCBP, and SiCzCz are electron-rich p-type materials, and mCBP-2CN, TSPO1, PPF, and SiTrzCz2 are electron-deficient n-type materials. All the blue light host materials have a unipolar characteristic. For the n-type material, because electron transport efficiency is higher than hole transport efficiency, causing a combination zone of holes and electrons to offset to a hole transport side. On the contrary, for the p-type material, because electron transport efficiency is lower than hole transport efficiency, causing the combination zone of holes and electrons to offset to an electron transport side. The offset of the combination zone reduces light-emitting efficiency.

In view of the technical problem in the related technologies, according to an aspect, an embodiment of this disclosure provides a compound. The compound includes a tetraphenyl silyl group, a carbazole group, and a triazine group, and the carbazole group and the triazine group are respectively connected to different benzene rings of the tetraphenyl silyl group. The triazine group includes a triazine ring and a first aryl substituent and a second aryl substituent that are connected to the triazine ring.

The compound provided in this embodiment of this disclosure uses the tetraphenyl silyl group as a central group of the compound, silicon in the tetraphenyl silyl group is SP3 hybridized, and a spatial structure of the silicon is a regular tetrahedron structure. This can effectively interrupt conjugation in a molecule of the compound, and help the molecule of the compound maintain a wide bandgap. The compound is connected to the carbazole group and the triazine group on different benzene rings of the tetraphenyl silyl group, where the carbazole group is electron-rich, facilitating hole injection and transport, and is used as a hole transport group. The triazine group is electron-deficient, facilitating electron injection and transport. It can be learned that the compound has both a hole transport group and an electron transport group, and therefore has bipolarity. The bipolar compound can achieve a balance between hole transport and electron transport. When the bipolar compound is used as a host material of a light-emitting layer of an OLED, this not only facilitates an exciton recombination zone to be located at a center of the light-emitting layer, but also facilitates widening of the exciton recombination zone. In addition, the triazine group includes the triazine ring and the first aryl substituent and the second aryl substituent that are connected to the triazine ring. A structure of the triazine group has advantages of a high triplet energy level and stable electron injection energy. With the structural features of the compound, the compound has a high triplet energy level when used as the host material of the light-emitting layer. In this way, excitons can be effectively injected into a guest material and a sensitizer and energy transfer can be performed, thereby improving light-emitting efficiency. In addition, this helps reduce a difference between triplet and singlet energy levels, so that a triplet exciton can be converted into a singlet exciton through reverse intersystem crossing, to reduce triplet annihilation, thereby prolonging a lifetime.

It should be noted that excitons generated in the light-emitting layer are classified into singlet excitons and triplet excitons. The singlet excitons can quickly transit back to a ground state to generate light, and the triplet excitons transit back to the ground state at a low speed, resulting in a large quantity of triplet excitons aggregating in the light-emitting layer, and causing annihilation of the triplet excitons. In this case, the efficiency and lifetime of the light-emitting layer is reduced. The compound provided in this embodiment of this disclosure reduces the energy level difference (ΔEₛₜ) between the singlet energy level and the triplet energy level, so that the triplet exciton become a singlet exciton through reverse intersystem crossing, to mitigate the foregoing technical problem.

In this embodiment of this disclosure, the carbazole group and the triazine group are respectively connected to different benzene rings of the tetraphenyl silyl group. In some examples, one or more carbazole groups exist on one benzene ring of the tetraphenyl silyl group, and the triazine group exists on another benzene ring of the tetraphenyl silyl group. In other words, the carbazole group and the triazine group are connected only to two benzene rings of the tetraphenyl silyl group.

The triazine group includes the triazine ring and the first aryl substituent and the second aryl substituent that are connected to the triazine ring. In some examples, the triazine ring is derived from 1,3,5-triazine, and has a higher triplet energy level and stable electron injection energy.

In some examples, the first aryl substituent and the second aryl substituent in the triazine group are independently selected from phenyl, dibenzofuranyl, naphthyl, anthryl, phenanthryl, fluorenyl, benzanthracenyl, benzophenanthrenyl, pyrenyl, or dibenzothiophenyl.

The first aryl substituent and the second aryl substituent may be the same or different, and are separately selected from the foregoing involved aryl groups. In this way, an electronic structure is further optimized, and stability of the triazine group is further improved.

In some examples, in the compound provided in this embodiment of this disclosure, there may be one to five carbazole groups, for example, one or two carbazole groups. This helps simplify a preparation process of the compound. The carbazole group may substitute for any substitutable position on a benzene ring on which the carbazole group is located. When there are two carbazole groups, the two carbazole groups may substitute for two different substitutable positions on a same benzene ring.

In some examples, in the compound provided in this embodiment of this disclosure, there may be one to five triazine groups, for example, one or two triazine groups. This helps simplify the preparation process of the compound. The triazine group may substitute for any substitutable position on a benzene ring on which the triazine group is located. When there are two triazine groups, the two triazine groups may substitute for two different substitutable positions on a same benzene ring.

In some implementations, in the compound provided in this embodiment of this disclosure, the tetraphenyl silyl group, the carbazole group, the first aryl substituent, and the second aryl substituent are separately substituted or unsubstituted, and for those groups having substituted groups, the substituted groups are independently selected from alkyl, aryl, cyano, deuterium atom, or halogen atom.

For example, the alkyl includes but is not limited to: methyl, isopropyl, tert-butyl, adamantyl, and the like. The aryl includes but is not limited to: phenyl, naphthyl, anthryl, phenanthryl, benzanthracenyl, benzophenanthrenyl, pyrenyl, and the like. The halogen atom may be a fluorine atom, a chlorine atom, a bromine atom, or the like. For example, the halogen atom is the fluorine atom.

With reference to the foregoing related descriptions of the compound, in some implementations, a chemical structural formula of the compound is shown as follows:

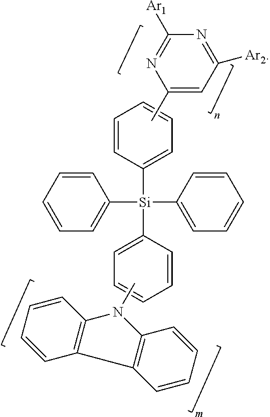

Ar₁ is the first aryl substituent, and Ar₂ is the second aryl substituent; and m and n are independently selected from integers from 1 to 5.

For example, the first aryl substituent and the second aryl substituent are independently selected from phenyl, dibenzofuranyl, naphthyl, anthryl, phenanthryl, fluorenyl, benzanthracenyl, benzophenanthrenyl, pyrenyl, or dibenzothiophenyl.

For example, each of m and n is independently 1 or 2.

With reference to the chemical structural formula of the compound, in an example, the chemical structural formula of the compound is further as follows:

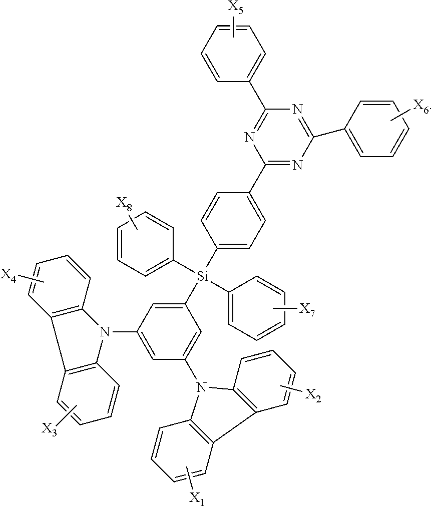

In the compound, the tetraphenyl silyl group, the carbazole group, phenyl corresponding to the first aryl substituent, and phenyl corresponding to the second aryl substituent are separately substituted or unsubstituted.

For those groups having substituted groups, X₁ to X₈ are substituted groups, and the substituted groups are independently selected from alkyl, aryl, cyano, deuterium atom, or halogen atom.

In some examples, each of quantities of X₁ to X₈ is independently one or more. For example, when allowed by a substitute position, the quantity may alternatively be two, three, four, five, or the like.

The compound having the chemical structural formula is particularly suitable as a blue light host material, and can effectively improve efficiency and a lifetime of a blue light-emitting layer.

With reference to the chemical structural formula of the compound, in another example, the chemical structural formula of the compound is further as follows:

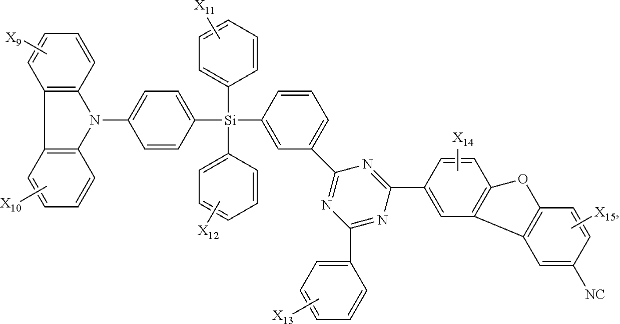

In the compound, the tetraphenyl silyl group, the carbazole group, phenyl corresponding to the first aryl substituent, and dibenzofuranyl corresponding to the second aryl substituent are separately substituted or unsubstituted.

For those groups having substituted groups, each of X₉ to X₁₅ is independently a substituted group, and the substituted groups are independently selected from alkyl, aryl, cyano, deuterium atom, or halogen atom.

In some examples, each of quantities of X₉ to X₁₅ is independently one or more. For example, when allowed by a substitute position, the quantity may alternatively be two, three, four, five, or the like.

The compound having the chemical structural formula is particularly suitable as a blue light host material, and can effectively improve efficiency and a lifetime of a blue light-emitting layer.

According to another aspect of embodiments of this disclosure, a light-emitting layer raw material is further provided. The light-emitting layer raw material includes a host material and a guest material, and any one of the compounds in the foregoing embodiment of this disclosure is used as the host material.

The light-emitting layer raw material provided in this embodiment of this disclosure can be used in an OLED to form a light-emitting layer, and the foregoing compound can be used as a host material in the light-emitting layer. The light-emitting layer raw material provided in this embodiment of this disclosure has all the advantages of the bipolar compound.

In some examples, the compound provided in this embodiment of this disclosure is used as a blue light host material in the light-emitting layer raw material. The compound may be used alone as the blue light host material, or may be used with another host material to form the blue light host material.

In some examples, a mass percentage of the host material in the light-emitting layer material is 70% to 99%, and may be further 80% to 95%, including but not limited to 70%, 73%, 75%, 77%, 78%, 79%, 80%, 81%, 82%, 83%, 84%, 85%, 86%, 87%, 88%, 89%, 90%, 91%, 92%, 93%, 94%, 95%, 96%, 97%, 98%, and 99%.

In some examples, the light-emitting layer material is a binary material system. In this case, a mass percentage of the guest material is the remaining percentage.

In some other examples, the light-emitting layer raw material further includes a sensitizer. In other words, the light-emitting layer material may be a ternary material system, and includes a host material, a guest material, and a sensitizer. A mass percentage of the sensitizer in the light-emitting layer material is 5% to 30%, and may be further 5% to 20%, including but not limited to 5%, 6%, 7%, 8%, 9%, 10%, 11%, 12%, 13%, 14%, 15%, 16%, 17%, 18%, 19%, 20%, 25%, 27%, 30%, and the like.

The light-emitting layer raw material provided in this embodiment of this disclosure may be used as a blue light-emitting layer raw material. The guest material that is collaborative with the host material based on the compound may be a fluorescent material, a phosphorescent material, or a thermally activated delayed fluorescence (TADF) material. The sensitizer that is collaborative with the host material based on the compound may be a phosphorescent material or a TADF material.

The TADF material features a small difference between singlet and triplet energy levels, so that a triplet exciton can be converted into a singlet exciton by using a reverse intersystem crossing process, to perform radiative transition and light emission. An advantage of the TADF material is that a triplet exciton can be used without introducing heavy metals, and a maximum exciton utilization of 100% can be reached.

For the guest material, some applicable blue fluorescent materials include but are not limited to perylene, TBPe, TBPDP, MADN, and the like; some applicable blue phosphorescent materials include but are not limited to FIrppy, FIrpic, FIr6, (CF3ppy)2Ir(pic), FIrtaz, PLON-7-dtb, PTON-TBBI, and the like; and some applicable blue TADF materials include but are not limited to SpiroAC-TRZ, BCz-TRz, 2CzPN, DMAC-TRZ, DABANA-1, t-DABANA, v-DABANA, and the like.

For the sensitizer, some applicable phosphorescent sensitizers include but are not limited to Ir(dpbic)₃, Ir(cb)₃, Ir(ppy)2acac, CN—Ir, PtON7-dtb, PtON-TBBI, and the like; some applicable TADF-type sensitizers include but are not limited to TPh2Cz2DPhCzBN, PCzTrz, PPCzTrz, and the like.

According to still another aspect of embodiments of this disclosure, an organic light-emitting device is further provided. The organic light-emitting device includes a cathode, an anode, and an organic functional layer, and the organic functional layer includes a light-emitting layer and is located between the cathode and the anode. The light-emitting layer is prepared by using any one of the foregoing light-emitting layer raw materials.

The organic light-emitting device provided in this embodiment of this disclosure is an organic electroluminescent device (OLED), and has all the advantages of the foregoing light-emitting layer raw material, so that the organic light-emitting device has high efficiency and a longer lifetime.

In some examples, the organic functional layer includes the light-emitting layer (EML) and a hole transport zone and an electron transport zone that are located on two sides of the light-emitting layer, where the anode, the hole transport zone, the light-emitting layer, the electron transport zone, and the cathode are sequentially stacked.

The hole transport zone includes at least one of a hole transport layer (HTL), a hole injection layer (HIL), and an electron blocking layer (EBL). The electron transport zone includes at least one of an electron transport layer (ETL), an electron injection layer (EIL), and a hole blocking layer (HBL).

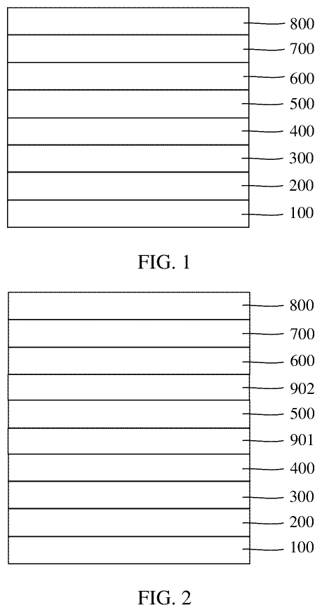

Refer to FIG. 1. An example of a structural arrangement of an organic light-emitting device is as follows: The organic light-emitting device includes a substrate 100, an anode 200, a hole injection layer 300, a hole transport layer 400, a light-emitting layer 500, an electron transport layer 600, an electron injection layer 700, and a cathode 800 that are sequentially stacked.

Refer to FIG. 2. Another example of a structural arrangement of an organic light-emitting device is as follows: The organic light-emitting device includes a substrate 100, an anode 200, a hole injection layer 300, a hole transport layer 400, an electron blocking layer 901, a light-emitting layer 500, a hole blocking layer 902, an electron transport layer 600, an electron injection layer 700, and a cathode 800 that are sequentially stacked.

In addition, the organic light-emitting device provided in this embodiment of this disclosure may be partially packaged, fully packaged, or not packaged, and the organic light-emitting device may be top-emitting or bottom-emitting.

The anode is usually formed on the substrate. The substrate may be a rigid substrate or a flexible substrate. The rigid substrate includes but is not limited to one or more of glass, ceramic, and metal foil. The flexible substrate includes but is not limited to polyethylene terephthalate (PET), polyethylene naphthalate (PEN), polyether ether ketone (PEEK), polyimide (PI), and the like.

The anode, the hole injection layer, the hole transport layer, the electron blocking layer, the electron transport layer, the electron injection layer, the hole blocking layer, the cathode, and the like may use respective common materials in the art, to collaborate with the light-emitting layer, thereby improving efficiency and a lifetime of the organic light-emitting device.

According to yet another aspect of embodiments of this disclosure, an embodiment of this disclosure further provides an electronic device. The electronic device includes any one of the foregoing organic light-emitting devices and has all the advantages of the organic light-emitting device.

In some examples, the organic light-emitting device provided in this embodiment of this disclosure may be used to prepare a display of the electronic device. The electronic device includes but is not limited to a mobile phone, a computer, a tablet computer, a television, a telephone, a virtual reality or augmented reality display, a vehicle-mounted display, and the like.

According to still yet another aspect of embodiments of this disclosure, a preparation method of a compound is further provided, where the compound is as described in any one of the foregoing. The preparation method of the compound includes: determining, based on a chemical structure of the compound, an organoboron monomer and a halide monomer that are used to synthesize the compound; and performing a coupling reaction on the organoboron monomer and the halide monomer, to prepare the compound.

In this embodiment of this disclosure, the organoboron monomer and the halide monomer that are used to synthesize the compound are determined based on the chemical structure of the compound. In this way, the monomers are connected based on the coupling reaction, to prepare the compound.

In some implementations, the compound is directly synthesized by performing the coupling reaction on the organoboron monomer and the halide monomer. In this implementation, the organoboron monomer contains a carbazole group and a tetraphenyl silyl group, and the halide monomer contains a triazine group. In this case, the organoboron monomer is prepared by using the following method: providing tetraphenyl silane having a carbazole group and a halogen group; and performing a borylation reaction on the tetraphenyl silane having the carbazole group and the halogen group and bis(pinacolato)diboron, to obtain the organoboron monomer.

A ready-made compound product may be directly used as the tetraphenyl silane having the carbazole group and the halogen group, or the tetraphenyl silane having the carbazole group and the halogen group may be obtained through self-preparation. For example, the tetraphenyl silane having the carbazole group and the halogen group is prepared by using the following method: performing a coupling reaction on a silane monomer containing a halogen group and a carbazole monomer containing a halogen group, to prepare the tetraphenyl silane having the carbazole group and the halogen group.

Reaction conditions (including a reaction temperature, a reaction time, a solvent, and the like) and parameters such as a catalytic environment related to the coupling reaction and the borylation reaction, and the like are adaptively determined based on an actual to-be-synthesized substance and a related raw material, to ensure that the coupling reaction and the borylation reaction can be smoothly implemented.

As an example (1), a compound 1 is provided, and a chemical structural formula of the compound 1 is shown as follows:

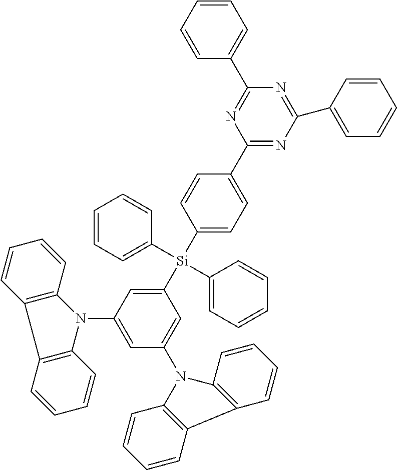 [SMILES: c1ccc(-c2nc(-c3ccccc3)nc(-c3ccc([Si](c4ccccc4)(c4ccccc4)c4cc(-n5c6ccccc6c6ccccc65)cc(-n5c6ccccc6c6ccccc65)c4)cc3)n2)cc1]

With reference to the following preparation equation of the compound 1, a preparation method of the compound 1 includes the following steps.

Step S11: Perform a coupling reaction on a silane monomer containing a halogen group and a carbazole monomer containing a halogen group, to prepare tetraphenyl silane having a carbazole group and a halogen group.

Step S12: Perform a borylation reaction on the tetraphenyl silane having the carbazole group and the halogen group and bis(pinacolato)diboron, to prepare an organoboron monomer.

Step S13: Perform a coupling reaction on the organoboron monomer and a halide monomer to prepare the compound 1.

The preparation equation of the compound 1 is as follows:

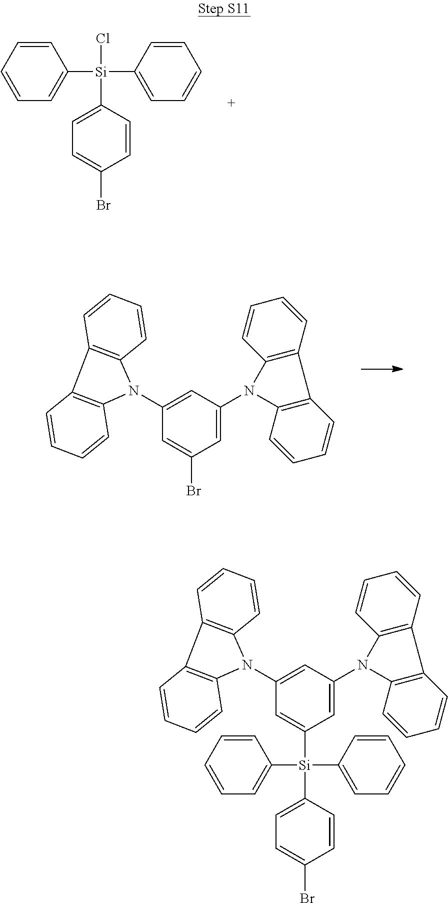 [SMILES: Cl[Si](c1ccccc1)(c1ccccc1)c1ccc(Br)cc1 ; Brc1cc(-n2c3ccccc3c3ccccc32)cc(-n2c3ccccc3c3ccccc32)c1 ; Brc1ccc([Si](c2ccccc2)(c2ccccc2)c2cc(-n3c4ccccc4c4ccccc43)cc(-n3c4ccccc4c4ccccc43)c2)cc1]

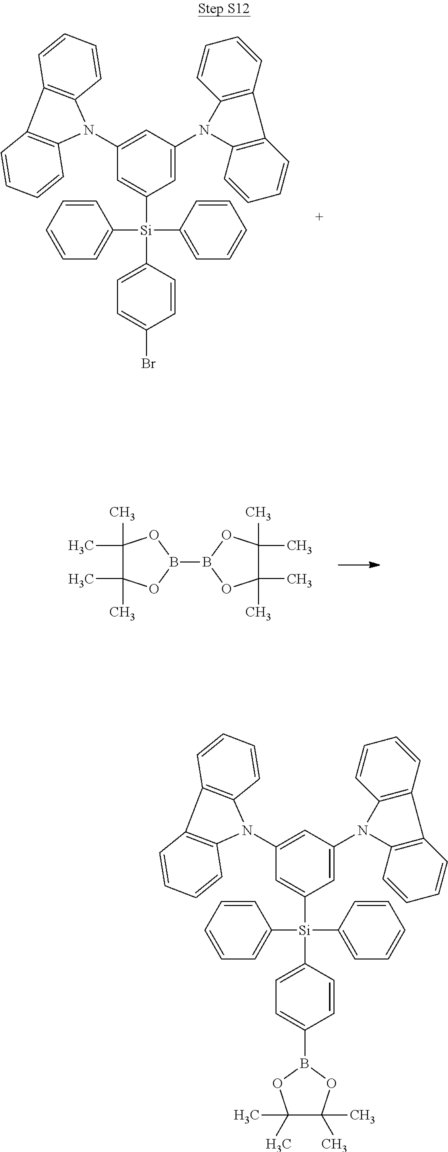

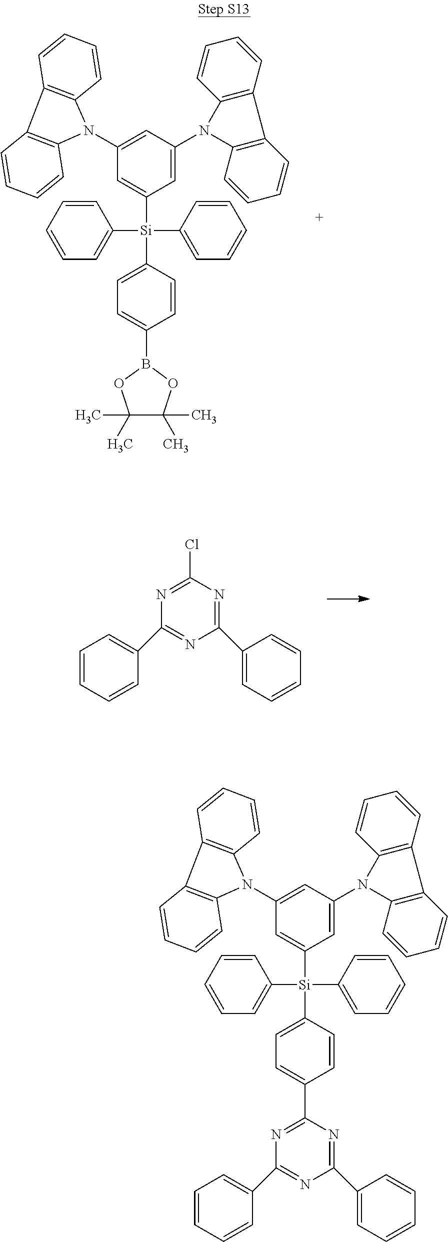 [SMILES: CC1(C)OB(c2ccc([Si](c3ccccc3)(c3ccccc3)c3cc(-n4c5ccccc5c5ccccc54)cc(-n4c5ccccc5c5ccccc54)c3)cc2)OC1(C)C ; Clc1nc(-c2ccccc2)nc(-c2ccccc2)n1 ; c1ccc(-c2nc(-c3ccccc3)nc(-c3ccc([Si](c4ccccc4)(c4ccccc4)c4cc(-n5c6ccccc6c6ccccc65)cc(-n5c6ccccc6c6ccccc65)c4)cc3)n2)cc1]

In some other implementations, a precursor of the compound is synthesized by performing the coupling reaction on the organoboron monomer and the halide monomer; and the compound is further prepared by grafting an aryl substituent onto the precursor of the compound.

In this implementation, the organoboron monomer contains a carbazole group and a tetraphenyl silyl group, and the halide monomer contains a triazine group. In this case, the organoboron monomer is prepared by using the following method: providing tetraphenyl silane having a carbazole group and a halogen group; and performing a borylation reaction on the tetraphenyl silane having the carbazole group and the halogen group and bis(pinacolato)diboron, to obtain the organoboron monomer.

This manner is applicable to grafting at least one of a first aryl group and a second aryl group that have a complex structure onto the precursor of the compound. The grafting process may be completed by performing a coupling reaction on the organoboron monomer containing a target aryl substituent and the precursor of the compound.

A ready-made compound product may be directly used as the tetraphenyl silane having the carbazole group and the halogen group, or the tetraphenyl silane having the carbazole group and the halogen group may be obtained through self-preparation. For example, the tetraphenyl silane having the carbazole group and the halogen group may be prepared by using the following method: performing a coupling reaction on a silane monomer containing a halogen group and a carbazole monomer containing a halogen group, to prepare a precursor of the tetraphenyl silane having the carbazole group and the halogen group; and grafting aryl containing a halogen substituent onto the precursor of the tetraphenyl silane, to prepare the tetraphenyl silane having the carbazole group and the halogen group.

A ready-made compound product may be directly used as the organoboron monomer containing the target aryl substituent, or the organoboron monomer containing the target aryl substituent may be obtained through self-preparation. For example, the organic boron monomer containing the target aryl substituent may be prepared by using the following method: providing a target aryl compound, and performing a borylation reaction on the target aryl compound and bis(pinacolato)diboron, to obtain the organoboron monomer containing the target aryl substituent. The target aryl compound is used to provide the target aryl substituent. A ready-made compound product may be directly used as the target aryl compound, or the target aryl compound may be obtained through self-preparation. For example, the target aryl compound may be synthesized by grafting a substituent onto a precursor compound of the target aryl compound through a coupling reaction.

As an example (2), a compound 2 is provided, and a chemical structural formula of the compound 2 is shown as follows:

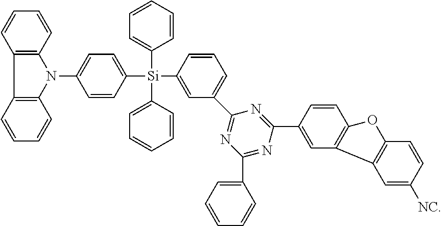

With reference to the following preparation equation of the compound 2, a preparation method of the compound 2 includes the following steps.

Step S21: Perform a coupling reaction on a silane monomer containing a halogen group and a carbazole monomer containing a halogen group, to prepare a precursor of tetraphenyl silane having a carbazole group and a halogen group; and graft aryl containing a halogen substituent onto the precursor of the tetraphenyl silane, to prepare the tetraphenyl silane having the carbazole group and the halogen group.

Step S22: Perform a borylation reaction on the tetraphenyl silane having the carbazole group and the halogen group and bis(pinacolato)diboron, to prepare an organoboron monomer.

Step S23: Perform a coupling reaction on the organoboron monomer and a halide monomer to prepare a precursor of the compound 2.

Step S24: Graft an aryl substituent onto the precursor of the compound 2, to prepare the compound 2. This includes: performing a coupling reaction on the organoboron monomer containing a target aryl substituent and the precursor of the compound 2, to complete the compound 2. In the compound 2, the target aryl substituent is a cyano-substituted dibenzofuranyl group.

For the organoboron monomer containing the target aryl substituent, refer to step S240. The organoboron monomer may be prepared by using the following method: synthesizing a target aryl compound by grafting a substituent onto a precursor compound of the target aryl compound through a coupling reaction; and performing a borylation reaction on the target aryl compound and bis(pinacolato)diboron, to obtain the organoboron monomer containing the target aryl substituent.

The preparation equation of the compound 2 is as follows:

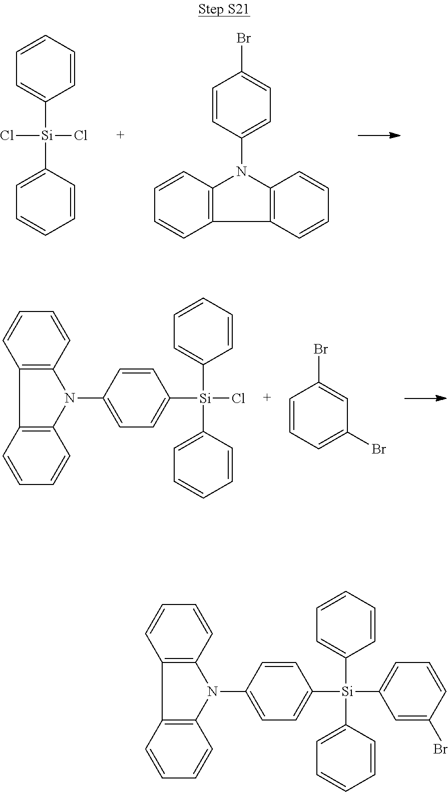 [SMILES: Cl[Si](Cl)(c1ccccc1)c1ccccc1 ; Brc1ccc(-n2c3ccccc3c3ccccc32)cc1 ; Cl[Si](c1ccccc1)(c1ccccc1)c1ccc(-n2c3ccccc3c3ccccc32)cc1 ; Brc1cccc(Br)c1 ; Brc1cccc([Si](c2ccccc2)(c2ccccc2)c2ccc(-n3c4ccccc4c4ccccc43)cc2)c1]

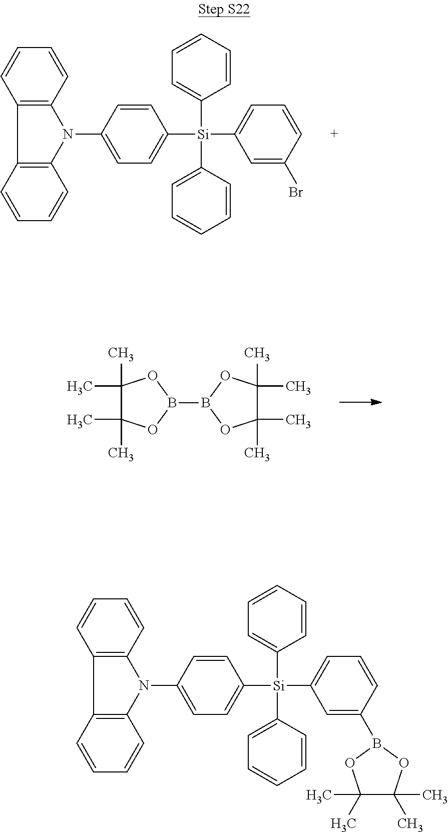

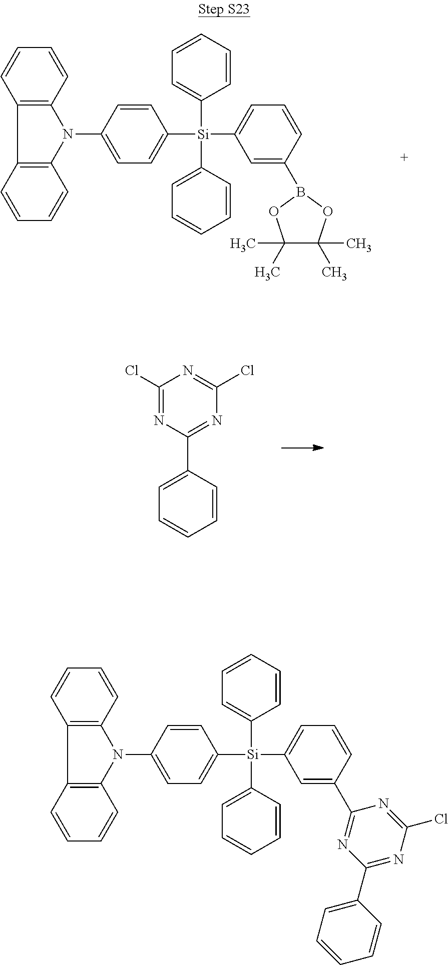 [SMILES: CC1(C)OB(c2cccc([Si](c3ccccc3)(c3ccccc3)c3ccc(-n4c5ccccc5c5ccccc54)cc3)c2)OC1(C)C ; Clc1nc(Cl)nc(-c2ccccc2)n1 ; Clc1nc(-c2ccccc2)nc(-c2cccc([Si](c3ccccc3)(c3ccccc3)c3ccc(-n4c5ccccc5c5ccccc54)cc3)c2)n1]

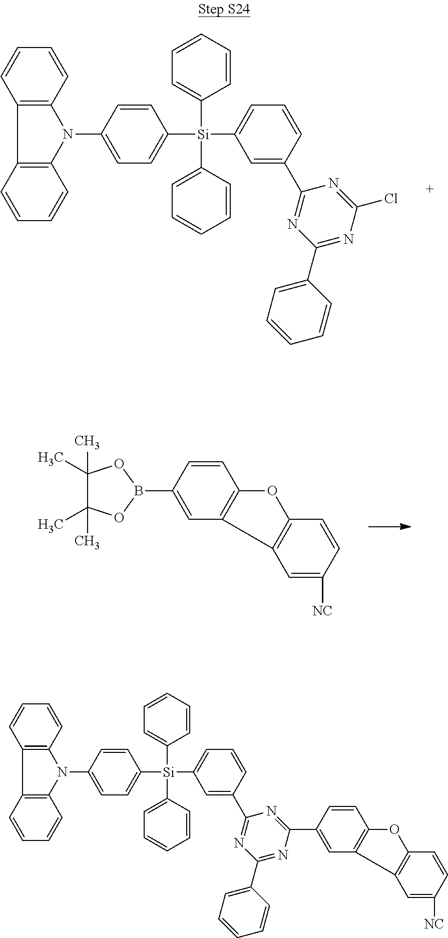 [SMILES: Clc1nc(-c2ccccc2)nc(-c2cccc([Si](c3ccccc3)(c3ccccc3)c3ccc(-n4c5ccccc5c5ccccc54)cc3)c2)n1 ; CC1(C)OB(c2ccc3oc4ccc(C#N)cc4c3c2)OC1(C)C ; N#Cc1ccc2oc3ccc(-c4nc(-c5ccccc5)nc(-c5cccc([Si](c6ccccc6)(c6ccccc6)c6ccc(-n7c8ccccc8c8ccccc87)cc6)c5)n4)cc3c2c1]

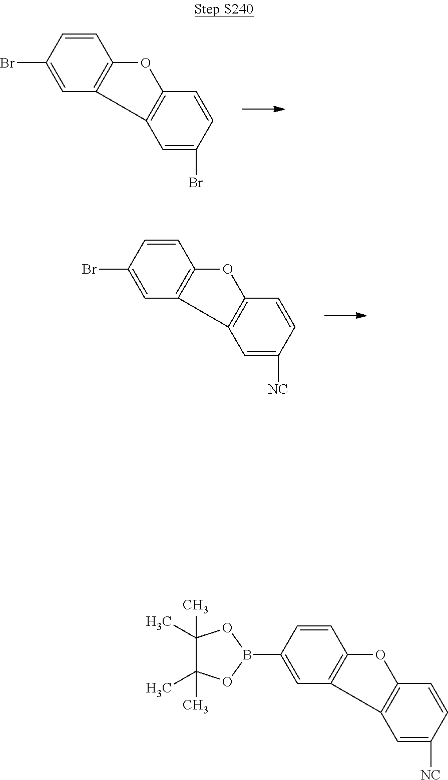 [SMILES: Brc1ccc2oc3ccc(Br)cc3c2c1 ; N#Cc1ccc2oc3ccc(Br)cc3c2c1 ; CC1(C)OB(c2ccc3oc4ccc(C#N)cc4c3c2)OC1(C)C]

The following describes specific implementations of the present invention in more detail. Although the following describes specific implementations of the present invention, it should be understood that the present invention may be implemented in various forms and should not be limited to the implementations described herein. If no specific technology or condition is specified in embodiments, a technology or condition described in the literature in the art or a product specification shall be followed. All reagents, materials, or instruments used with no indication of manufacturers are conventional products that are commercially available.

### Embodiment 1

In Embodiment 1, the compound 1 is prepared. With reference to the preparation equation of the compound 1, preparation steps of the compound 1 are as follows:

(1) Synthesize tetraphenyl silane containing a carbazole group and bromo. Refer to Step S11. This includes: In an environment protected by nitrogen, 9,9′-(5-bromo-1,3-phenylene)bis(9H-carbazole) (30.0 g, 62 mmol) is dissolved in 300 mL of anhydrous tetrahydrofuran. nBuLi (70 mmol) is slowly added at a temperature of −78° C., and stirred for 1 hour. An obtained reaction solution is added to 300 mL of a tetrahydrofuran solution containing p-bromophenyl diphenyl chlorosilane (24 g, 65 mmol, CAS number: 18557-79-4), and slowly heated to a room temperature, for reaction overnight, to synthesize the tetraphenyl silane containing the carbazole group and the bromo.

An H nuclear magnetic resonance testing result of the tetraphenyl silane containing the carbazole group and the bromo is shown as follows: ¹HNMR (500 MHz, CDCl₃): δ (ppm) 8.15 (d, 2H), 7.85 (d, 2H), 7.70 (dd, 4H), 7.59 (d, 2H), 7.45 to 7.30 (m, 16H), 7.25 (d, 2H), 7.15 (s, 1H).

(2) Synthesize an organoboron monomer. Refer to Step S12. This includes: In a nitrogen atmosphere, the synthesized tetraphenyl silane (15.0 g, 20 mmol) containing the carbazole group and the bromo is dissolved in 200 mL of tetrahydrofuran. nBuLi (30 mmol) is slowly added at a temperature of −78° C., and stirred for 1 hour. Bis(pinacolato)diboron (7.5 g, 30 mmol) is then slowly added to a reaction system, and the reaction system is heated to the room temperature, for reaction overnight, to synthesize the organoboron monomer.

An H nuclear magnetic resonance testing result of the organoboron monomer is shown as follows: ¹HNMR (500 MHz, CDCl₃): δ (ppm) 8.15 (d, 2H), 7.83 (d, 2H), 7.70 (dd, 4H), 7.59 (d, 2H), 7.45 to 7.30 (m, 16H), 7.25 (d, 2H), 7.15 (s, 1H), 1.30 (s, 12H).

(3) Synthesize the compound 1. Refer to Step S13. This includes: In the nitrogen atmosphere, the synthesized organoboron monomer (6.4 g, 8 mmol), 2-chloro-4,6-diphenyl-1,3,5-triazine (2.6 g, 10 mmol), tetrakis(triphenylphosphine) palladium (0.50 g, 0.4 mmol), 15 mL of a 2 mol/L K₂CO₃ solution, and 15 mL of ethanol are dissolved in 60 mL of toluene, for reaction at a reflux temperature for 20 hours, to synthesize the compound 1. According to an H nuclear magnetic resonance testing, a chemical structure of the compound 1 is consistent with the chemical structure shown in this embodiment of this disclosure.

In Embodiment 1, an energy level of the compound 1 is further tested based on a quantum chemistry principle, and a testing result is shown in Table 1.

TABLE 1

| Item | HOMO | LUMO | Bandgap | T₁ | S₁ | ΔE_{ST} |
|---|---|---|---|---|---|---|
| Compound 1 | −5.55 | −2.18 eV | 3.37 eV | 2.96 | 3.05 | 0.09 |
| | eV | | | eV | eV | eV |

In Table 1, the HOMO energy level indicates an energy level corresponding to a highest occupied molecular orbital. The LUMO energy level indicates an energy level corresponding to a lowest unoccupied molecular orbital.

Bandgap indicates an energy level difference between the HOMO energy level and the LUMO energy level; and T1 is a triplet energy level, S1 is a singlet energy level, and ΔE_{ST} is an energy level difference between the singlet energy level S1 and the triplet energy level T1.

It can be learned from Table 1 that the compound 1 has a high triplet energy level, which results in a small energy level difference between the singlet energy level S1 and the triplet energy level T1. The small energy level difference can effectively drive efficient conversion of a triplet exciton into a singlet exciton, so that a host material based on the compound 1 effectively transfers energy to a guest material or a sensitizer.

In Embodiment 1, stability of the compound 1 and a known blue light host material mCBP is further tested, where a chemical structural formula of the blue light host material mCBP is shown as follows:

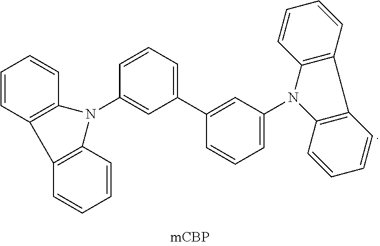 [SMILES: c1cc(-c2cccc(-n3c4ccccc4c4ccccc43)c2)cc(-n2c3ccccc3c3ccccc32)c1]

On the one hand, bond energy between the carbazole group and a connected benzene ring of the compound 1 and bond energy between a carbazole group and a connected benzene ring of the compound mCBP is tested. Specifically, for related bond energy data of the compound 1 and the compound mCBP in a neutral condition, a cation condition, and an anion condition, a testing result is shown in Table 2.

TABLE 2

| Item | Neutral condition | Cation condition | Anion condition |
|---|---|---|---|
| mCBP | 3.90 eV | 4.73 eV | 2.09 eV |
| Compound 1 | 3.93 eV | 5.08 eV | 3.05 eV |

It can be learned from Table 2 that the molecular bond energy of the compound 1 in Embodiment 1 of this disclosure is higher than that of mCBP under different conditions. This indicates that the stability of the compound 1 is higher than that of mCBP, so that the compound 1 has a longer lifetime.

On the other hand, hole and electron transport capabilities of the compound 1 and the compound mCBP are tested. A testing result is shown in Table 3.

TABLE 3

| Item | λₕ | λₑ | λₕ/λₑ |
|---|---|---|---|
| mCBP | 0.047 eV | 0.482 eV | 0.098 |
| Compound 1 | 0.179 eV | 0.471 eV | 0.380 |

λₕ is a molecular reorganization energy of a hole, and λₑ is molecular reorganization energy of an electron. The two pieces of data can reflect hole and electron transport capabilities of a compound molecule. Smaller values of λₕ and μₑ indicate higher corresponding transport capabilities. In addition, a value of λₕ/λₑ closer to 1 indicates more balanced hole and electron transport capabilities.

It can be learned from Table 3 that the compound 1 in Embodiment 1 of this disclosure has a stronger hole and electron transport balance than mCBP, and therefore has higher efficiency and a longer lifetime.

### Embodiment 2

In Embodiment 2, the compound 2 is prepared. With reference to the preparation equation of the compound 2, preparation steps of the compound 2 are as follows:

(1) Synthesize tetraphenyl silane containing a carbazole group and bromo. Refer to Step S21. This includes: In an environment protected by nitrogen, 9-(4-bromophenyl) carbazole (30.0 g, 93 mmol) is dissolved in 300 mL of anhydrous tetrahydrofuran. nBuLi (93 mmol) is slowly added at a temperature of −78° C., and stirred for 1 hour. An obtained reaction solution is added to 300 mL of tetrahydrofuran solution containing dichlorodiphenylsilane (30 g, 120 mmol), and slowly heated to a room temperature, for reaction overnight, to synthesize a precursor of the tetraphenyl silane containing the carbazole group and the bromo.

An H nuclear magnetic resonance testing result of the precursor of the tetraphenyl silane is shown as follows: ¹HNMR (500 MHz, CDCl₃): δ (ppm) 8.13 (d, 2H), 7.85 (d, 2H), 7.70 (dd, 4H), 7.59 (d, 2H), 7.48 to 7.37 (m, 8H), 7.28 (d, 2H), 7.25 (d, 2H).

In the environment protected by nitrogen, 1,3-dibromobenzene (15.0 g, 60 mmol) is dissolved in 150 mL of anhydrous tetrahydrofuran. nBuLi (75 mmol) is slowly added at a temperature of −78° C., and stirred for 1 hour. Then, a reaction solution is added to tetrahydrofuran solution containing the precursor of the tetraphenyl silane (30 g, 120 mmol), and slowly heated to a room temperature, for reaction overnight, to synthesize the tetraphenyl silane containing the carbazole group and the bromo.

An H nuclear magnetic resonance testing result of the tetraphenyl silane containing the carbazole group and the bromo is shown as follows: ¹HNMR (500 MHz, CDCl₃): δ (ppm) 8.12 (d, 2H), 7.80 to 7.76 (m, 3H), 7.65 to 7.58 (m, 7H), 7.55 (d, 1H), 7.50 to 7.38 (m, 10H), 7.31 to 7.26 (dd, 3H). It can be learned that a chemical structure of the synthesized tetraphenyl silane is consistent with the chemical structure described in Step S21.

(2) Synthesize an organoboron monomer. Refer to Step S22. This includes: Under protection of nitrogen, the synthesized tetraphenyl silane (14.0 g, 24 mmol) is dissolved in 200 mL of tetrahydrofuran. nBuLi (30 mmol) is slowly added at −78° C., and stirred for 1 hour. Bis(pinacolato)diboron (7.5 g, 30 mmol) is then slowly added, a temperature of a reaction system is increased to the room temperature overnight, to synthesize the organoboron monomer.

An H nuclear magnetic resonance testing result of the organoboron monomer is shown as follows: ¹HNMR (500 MHz, CDCl₃): δ (ppm) 8.13 (d, 2H), 7.90 (d, 1H), 7.79 (d, 2H), 7.70 (d, 1H), 7.68 (dd, 3H), 7.64 (dd, 2H), 7.58 (dd, 2H), 7.49 to 7.37 (m, 10H), 7.28 to 7.24 (dd, 3H), 1.30 (s, 12H).

(3) Synthesize a precursor of the compound 2. Refer to Step S23. This includes: In the environment protected by nitrogen, 2,4-dichloro-6-phenyl-1,3,5-triazine (4.5 g, 20 mmol), the organoboron monomer (9.4 g, 15 mmol), tetrakis(triphenylphosphine) palladium (0.70 g, 0.6 mmol), 20 mL of a 2 mol/L K₂CO₃ solution, and 20 mL of ethanol are dissolved in 80 mL of toluene, for reaction at a reflux temperature for 20 hours, to synthesize the precursor of the compound 2.

An H nuclear magnetic resonance testing result of the precursor of the compound 2 is shown as follows: ¹HNMR (500 MHz, CDCl₃): δ (ppm) 9.08 (s, 1H), 8.75 (d, 1H), 8.51 (d, 1H), 8.14 (d, 2H), 7.90 (m, 3H), 7.75 to 7.64 (dd, 4H), 7.58 (dd, 2H), 7.52 (d, 1H), 7.50 to 7.46 (m, 10H), 7.38 to 7.34 (dd, 5H), 7.26 (dd, 4H).

(4) Synthesize the compound 2. Refer to Step S24. This includes: In the environment protected by nitrogen, the precursor (6.9 g, 10 mmol) of the compound 2, an organoboron monomer (number: 1638836-99-3) (3.2 g, 10 mmol) containing a cyano-substituted dibenzofuranyl group, tetrakis(triphenylphosphine) palladium (0.50 g, 0.4 mmol), 15 mL of a 2 mol/L K₂CO₃ solution, and 15 mL of ethanol are dissolved in 60 mL of toluene, for reaction at a reflux temperature for 20 hours, to synthesize the compound 2. According to an H nuclear magnetic resonance testing, a chemical structure of the compound 2 is consistent with the chemical structure shown in this embodiment of this disclosure.

In Embodiment 2, an energy level of the compound 2 is further tested based on a quantum chemistry principle, and a testing result is shown in Table 4.

TABLE 4

| Item | HOMO | LUMO | Bandgap | T₁ | S₁ | ΔΕ_{ST} |
|---|---|---|---|---|---|---|
| Compound 2 | −5.54 | −2.18 | 3.33 eV | 2.92 | 2.98 | 0.06 |
| | eV | eV | | eV | eV | eV |

It can be learned from Table 4 that the compound 2 has a high triplet energy level, which results in a small energy level difference between the singlet energy level S1 and the triplet energy level T1. The small energy level difference can effectively drive efficient conversion of a triplet exciton into a singlet exciton, so that a host material based on the compound 2 effectively transfers energy to a guest material or a sensitizer.

In Embodiment 2, stability of the compound 2 and a known blue light host material mCBP is further tested. On the one hand, bond energy between the carbazole group and a connected benzene ring of the compound 2 and bond energy between a carbazole group and a connected benzene ring of the compound mCBP is tested. Specifically, for related bond energy data of the compound 2 and the compound mCBP in a neutral condition, a cation condition, and an anion condition, a testing result is shown in Table 5.

TABLE 5

| Item | Neutral condition | Cation condition | Anion condition |
|---|---|---|---|
| mCBP | 3.90 eV | 4.73 eV | 2.09 eV |
| Compound 2 | 4.30 eV | 5.07 eV | 3.19 eV |

It can be learned from Table 5 that the molecular bond energy of the compound 2 in Embodiment 2 of this disclosure is higher than that of mCBP under different conditions. This indicates that the stability of the compound 2 is higher than that of mCBP, so that the compound 2 has a longer lifetime.

On the other hand, hole and electron transport capabilities of the compound 2 and the compound mCBP are tested. A testing result is shown in Table 6.

TABLE 6

| Item | λₕ | λₑ | λₕ/λₑ |
|---|---|---|---|
| mCBP | 0.047 eV | 0.482 eV | 0.098 |
| Compound 2 | 0.170 eV | 0.277 eV | 0.614 |

λₕ is a molecular reorganization energy of a hole, and λₑ is molecular reorganization energy of an electron. The two pieces of data can reflect hole and electron transport capabilities of a compound molecule. Smaller values of λₕ and λₑ indicate higher corresponding transport capabilities. In addition, a value of λₕ/λₑ closer to 1 indicates more balanced hole and electron transport capabilities.

It can be learned from Table 6 that the compound 2 in Embodiment 2 of this disclosure has a stronger hole and electron transport balance than mCBP, and therefore has higher efficiency and a longer lifetime.

### Embodiment 3

In Embodiment 3, the compound 1 in Embodiment 1 and the compound 2 in Embodiment 2 are used as testing examples, and the compound mCBP is used as a comparison example. The three compounds are separately tested for application in an OLED.

Specifically, the compound 1 (a host material) in Embodiment 1 of this disclosure is mixed with a blue phosphorescent material PtON-7-dtb (a guest material) at a mass ratio of 4:1, to form a light-emitting layer raw material to prepare a light-emitting layer, and an OLED 1 is prepared based on the light-emitting layer.

The compound 2 (a host material) in Embodiment 2 of this disclosure is mixed with the blue phosphorescent material PLON-7-dtb (a guest material) at a mass ratio of 4:1, to form a light-emitting layer raw material to prepare a light-emitting layer, and an OLED 2 is prepared based on the light-emitting layer.

The mCBP is used as a host material and is mixed with the blue phosphorescent material PtON-7-dtb (a guest material) at a mass ratio of 4:1, to form a light-emitting layer raw material to prepare a light-emitting layer comparison example, and an OLED comparison example is prepared based on the light-emitting layer comparison example.

The OLED 1, the OLED 2, and the OLED comparison example differ only in light-emitting layers, other layers are completely the same, and all the other layers are of known materials. In addition, test conditions of the OLED 1, the OLED 2, and the OLED comparison example are all the same.

The test condition and a test result of the OLED comparison example are used as reference conditions. Specifically, an operating voltage of the OLED comparison example is set to a reference voltage, and current light-emitting efficiency of the OLED comparison example is set to reference light-emitting efficiency. A group of data obtained through testing is that an operating voltage of the OLED 1 is 0.84 times the reference voltage, and current light-emitting efficiency of the OLED 1 is 1.2 times the reference light-emitting efficiency. An operating voltage of the OLED 2 is 0.75 times the reference voltage, and current light-emitting efficiency of the OLED 2 is 1.3 times the reference light-emitting efficiency.

It can be learned that, compared with the OLED comparison example, the OLED 1 and the OLED 2 obtain higher current light-emitting efficiency at lower operating voltages. Therefore, the compound 1 and the compound 2 provided in embodiments of this disclosure are particularly advantageous for improving device light-emitting efficiency and reducing device energy consumption compared with the known compound mCBP.

It should be noted that the chemical structural formula of the blue phosphorescent material PtON-7-dtb is shown as follows:

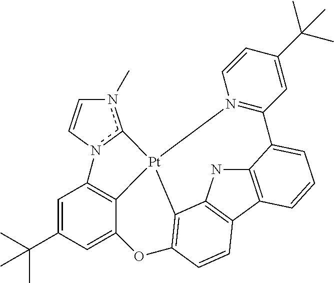

The foregoing descriptions are merely intended to help a person skilled in the art understand the technical solutions of this disclosure, and are not intended to limit this disclosure. Any modification, equivalent replacement, or improvement made without departing from the spirit and principle of this disclosure shall fall within the protection scope of this disclosure.

What is claimed is:

1. A compound comprising:
a tetraphenyl silyl group comprising a plurality of benzene rings;
a first carbazole group connected to a first benzene ring of the tetraphenyl silyl group; and
a first triazine group connected to a second benzene ring of the tetraphenyl silyl group, the second benzene ring being different from the first benzene ring, and the first triazine group comprising a triazine ring, a first aryl substituent, a second aryl substituent, the first and the second aryl substituents being connected to the triazine ring.

2. The compound according to claim 1, wherein the first aryl substituent is phenyl, dibenzofuranyl, naphthyl, anthryl, phenanthryl, fluorenyl, benzanthracenyl, benzophenanthrenyl, pyrenyl, or dibenzothiophenyl, and wherein the second aryl substituent is phenyl, dibenzofuranyl, naphthyl, anthryl, phenanthryl, fluorenyl, benzanthracenyl, benzophenanthrenyl, pyrenyl, or dibenzothiophenyl.

3. The compound according to claim 1, further comprising:
a second carbazole group or a second triazine group.

4. The compound according to claim 1, wherein one or more of the tetraphenyl silyl group, the first carbazole group, the first aryl substituent, and the second aryl substituent comprises one or more substituents, wherein the one or more substituents comprise alkyl, aryl, cyano, deuterium atom, or halogen atom.

5. The compound according to claim 1, wherein a chemical structural formula of the compound is: 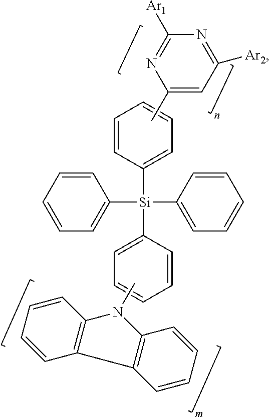
wherein
Ar₁ is the first aryl substituent, and Ar₂ is the second aryl substituent; and
m and n are each independently integers ranging from 1 to 5.

6. The compound according to claim 5, wherein the chemical structural formula of the compound is: 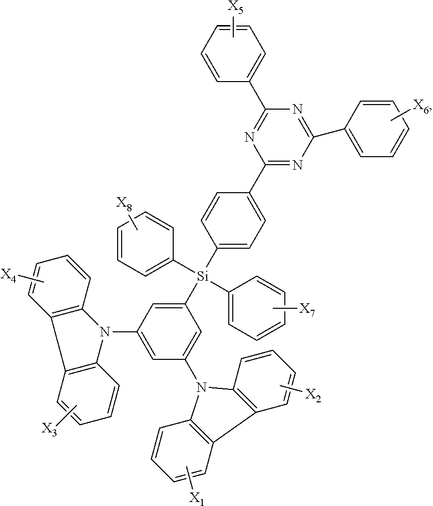
wherein
the tetraphenyl silyl group, the first carbazole group, the first aryl substituent corresponding to phenyl, and the second aryl substituent corresponding to phenyl are each independently substituted or unsubstituted; and
X₁ to X₈ are substituted groups and comprise alkyl, aryl, cyano, deuterium atom, or halogen atom.

7. The compound according to claim 5, wherein the chemical structural formula of the compound is: 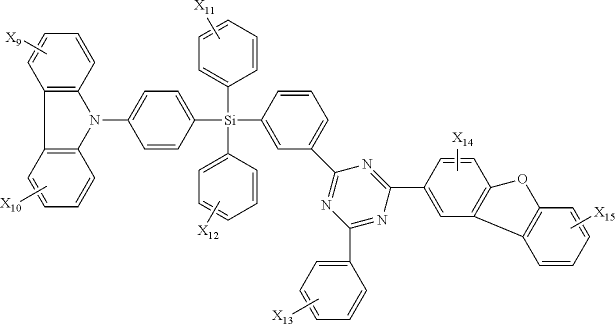
wherein
the tetraphenyl silyl group, the first carbazole group, the first aryl substituent corresponding to phenyl, and the second aryl substituent corresponding to dibenzofuranyl are each independently substituted or unsubstituted; and
X₉ to X₁₅ are substituted groups and comprise alkyl, aryl, cyano, deuterium atom, or halogen atom.

8. A light-emitting layer raw material comprising:
a guest material; and
a host material comprising a compound comprising
a tetraphenyl silyl group comprising a plurality of benzene rings;
a first carbazole group connected to a first benzene ring of the tetraphenyl silyl group; and
a first triazine group connected to a second benzene ring of the tetraphenyl silyl group, the second benzene ring being different from the first benzene ring, and the first triazine group comprising a triazine ring, a first aryl substituent, a second aryl substituent, the first and the second aryl substituents being connected to the triazine ring.

9. The light-emitting layer raw material according to claim 8, wherein the host material comprises a blue light host material.

10. The light-emitting layer raw material according to claim 8, wherein a mass percentage of the host material in the light-emitting layer raw material is 70% to 99%.

11. The light-emitting layer raw material according to claim 8, wherein the light-emitting layer raw material further comprises a sensitizer, and a mass percentage of the sensitizer in the light-emitting layer raw material is 5% to 30%.

12. The light-emitting layer raw material according to claim 8, wherein the first aryl substituent is phenyl, dibenzofuranyl, naphthyl, anthryl, phenanthryl, fluorenyl, benzanthracenyl, benzophenanthrenyl, pyrenyl, or dibenzothiophenyl, and wherein the second aryl substituent is phenyl, dibenzofuranyl, naphthyl, anthryl, phenanthryl, fluorenyl, benzanthracenyl, benzophenanthrenyl, pyrenyl, or dibenzothiophenyl.

13. The light-emitting layer raw material according to claim 8, wherein one or more of the tetraphenyl silyl group, the first carbazole group, the first aryl substituent, and the second aryl substituent comprises one or more substituents, wherein each of the one or more substituents is alkyl, aryl, cyano, deuterium atom, or halogen atom.

14. An organic light-emitting device comprising:
a cathode;
an anode; and
a light-emitting layer located between the cathode and the anode, the light-emitting layer comprises:
a guest material, and
a host material comprising a compound, the compound comprising
a tetraphenyl silyl group comprising a plurality of benzene rings,
a first carbazole group connected to a first benzene ring of the tetraphenyl silyl group, and
a first triazine group connected to a second benzene ring of the tetraphenyl silyl group, the second benzene ring being different from the first benzene ring, and the first triazine group comprising a triazine ring, a first aryl substituent, a second aryl substituent, the first and the second aryl substituents being connected to the triazine ring.

15. The organic light-emitting device according to claim 14, wherein the host material comprises a blue light host material.

16. The organic light-emitting device according to claim 14, wherein a mass percentage of the host material in the material of the light-emitting layer varies from 70% to 99%.

17. The organic light-emitting device according to claim 14, wherein the material of the light-emitting layer further comprises a sensitizer, and a mass percentage of the sensitizer in the material of the light-emitting layer is 5% to 30%.

18. The organic light-emitting device according to claim 14, wherein the first aryl substituent is phenyl, dibenzofuranyl, naphthyl, anthryl, phenanthryl, fluorenyl, benzanthracenyl, benzophenanthrenyl, pyrenyl, or dibenzothiophenyl, and wherein the second aryl substituent is phenyl, dibenzofuranyl, naphthyl, anthryl, phenanthryl, fluorenyl, benzanthracenyl, benzophenanthrenyl, pyrenyl, or dibenzothiophenyl.

19. The organic light-emitting device according to claim 14, wherein one or more of the tetraphenyl silyl group, the first carbazole group, the first aryl substituent, and the second aryl substituent comprises one or more substituents, wherein each of the one or more substituents is alkyl, aryl, cyano, deuterium atom, or halogen atom.

20. The organic light-emitting device according to claim 14, wherein a chemical structural formula of the compound is: 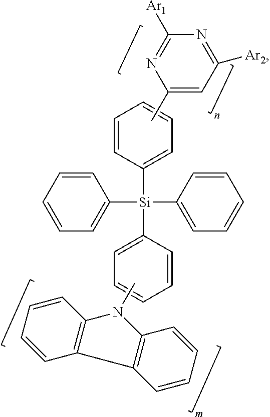
wherein
Ar₁ is the first aryl substituent, and Ar₂ is the second aryl substituent; and
m and n are each independently from integers ranging from 1 to 5.
